(19) United States
(12) Patent Application Publication
(10) Pub. No.: US 2026/0347996 A1
(43) Pub. Date: Nov. 5, 2026

(54) COMPOSITE ELEMENT

(71) Applicant: PLANSEE SE, Reutte (AT)

(72) Inventors: Malte LENZ, Reutte (AT); Michael MARK, Reutte (AT); Peter MALLAUN, Reutte (AT); Petra MAYR-SCHMÖLZER, Reutte (AT)

(21) Appl. No.: 19/486,113

(22) PCT Filed: Jun. 6, 2024
(86) PCT No.: PCT/AT2024/060221

§ 371 Date: Nov. 20, 2025

(30) Foreign Application Priority Data
Jun. 15, 2023 (AT) GM50104/2023

(51) Int. Cl. C23C 14/06; C23C 14/02; C23C 14/16; C23C 14/34; C23C 14/58

(52) U.S. Cl. CPC C23C 14/0635; C23C 14/025; C23C 14/16; C23C 14/3414; C23C 14/5846

(57) ABSTRACT

A composite body includes a main part made of a molybdenum-based material, on at least sections or portions of which a tungsten-carbide-containing coating is formed. The coating has a microstructure that consists or is formed substantially of fine or microcrystalline and/or nanocrystalline tungsten carbide grains. A method for producing a composite body is also provided.

The present invention relates to a composite body comprising a main body made of a molybdenum-based material having a coating.

Molybdenum exhibits outstanding chemical resistance to various media.

However, under oxygen, molybdenum is only resistant to approx. 250 °C.

For the application of molybdenum in oxidizing gases and elements, molybdenum is generally used in coated form to protect against oxidation.

For example, coatings based on silicon and boron (e.g., SIBOR®) are common.

The resistance of molybdenum is likewise limited by the presence of carbon at high temperatures, since molybdenum reacts with the carbon above about 800 °C to form MoC and then Mo₂C. Mo₂C and molybdenum have different coefficients of thermal expansion, which means that thermal stresses will lead to flaking and destruction of the surface.

Therefore, coatings are likewise proposed for the use of molybdenum under carburizing conditions.

For example, Kardoulaki et al. have described the problem of molybdenum reacting in graphitic reactors and discussed various nitride, oxide and carbide layers as possible solutions. Proposed therein as protective layers for molybdenum are TiC, ZrC, TaC, NbC and SiC.

See: Kardoulaki, E., Nizolek, T., Luther, E., & Swartz, M. (2021): On the Interactions of Molybdenum and Graphite, a Promising Material System for Microreactors, JOM, 73, 3499-3512; https://doi.org/10.1007/s11837-021-04876-8.

One of the disadvantages of the coatings mentioned therein is that the chemical compounds proposed are undesirable for certain thermal processes.

It is an object of the present invention to provide a composite body having a main body made of a molybdenum-based material that is resistant under carburizing conditions. In particular, the composite body shall not lead to contamination of an atmosphere in a heat-treatment device in which the composite body is used.

The object is achieved by a composite body having the features of claim 1.

Also described is a method for producing a composite body.

Preferred developments are specified in the dependent claims.

Since the composite body has:
a main body made of a molybdenum-based material on which a coating comprising tungsten carbide is formed at least sectionally, the coating having a microstructure substantially consisting of fine-crystalline and/or nanocrystalline tungsten carbide grains,
what is created is a composite body that is especially resistant under carburizing conditions.

In the context of this application, molybdenum-based material means a material having at least 50 at % (atomic percent) molybdenum. In particular, the content of molybdenum is greater than 90 at % and more preferably greater than 95 at %.

The main body may entirely consist of the molybdenum-based material.

Alternatively, the main body may be a material composite. In this case, the substrate bearing the coating and optionally an intermediate layer is a molybdenum-based material.

The coating comprises tungsten carbide.

In particular, the coating substantially consists of tungsten carbide.

“Substantially” in this context means that the coating consists of tungsten carbide to an extent of at least 80 vol % and more preferably consists of tungsten carbide to an extent of at least 90 vol %. In the context of the present application, tungsten carbide is understood to mean in particular the species WC and W₂C.

Especially preferably, the coating entirely consists of tungsten carbide with or without customary impurities.

The level of customary impurities is less than 1 at % (atomic percent) and preferably less than 0.1 at %.

The microstructure of the coating substantially consists of fine-crystalline and/or nanocrystalline tungsten carbide grains.

Here, “substantially” means that the microstructure largely consists of fine-crystalline and/or nanocrystalline tungsten carbide grains. In particular, at least 80%, preferably at least 90% and more preferably at least 95% of the microstructure are fine-crystalline and/or nanocrystalline tungsten carbide grains. The percentages are based on a quantitative structural analysis.

In other words, most of the coating has a fine-grained microstructure.

In particular, the microstructure is entirely fine-crystalline and/or nanocrystalline. According to this development, there are no coarse tungsten carbide grains or other structural constituents.

The aspect concerning the absence of other structural constituents, such as carbides of other metals, oxides, etc., is important because contamination by the coating is avoided.

Nanocrystalline in the context of this application refers to grains having a grain size of up to 100 nm (nanometers).

Fine-crystalline in this application is understood to mean a structure having grain sizes from 100 nm to a few um, preferably grain sizes from 100 nm to 5 μm (micrometers) and in particular grain sizes from 100 nm to 1 μm.

Coarse grains in this application are understood to mean grains having a grain size of greater than or equal to 10 um.

It is thus preferable that the coating is particularly fine-grained.

One of the advantages of this is that, even at extremely low layer thicknesses, the coating comprises a large number of grains along its thickness.

Another important advantage of a fine-grained structure of the coating is that the coating has a high level of hardness and strength. It is known that grain refinement is associated with an increase in yield strength. A fine grain thus leads to an increase in strength and hardness.

Furthermore, a coating having a fine-grained structure has a high level of fracture toughness. The fine-grained structure is advantageous with respect to crack propagation.

These mechanical properties of the coating are especially advantageous when using the composite body under cyclic thermal stress.

Preferably, a pore fraction in the coating is below 10%; more preferably, the pore fraction in the coating is below 5%, more preferably below 3% and yet more preferably below 1.5%.

The pore fraction can be determined by quantitative metallographic methods. We propose an evaluation such that an areal proportion of pores in the coating is determined on a metallographic cut of a sample and said areal proportion is related to the image section viewed.

An example of such a determination of the pore fraction of the coating is explained in the description of the drawings.

The advantages of the low pore fraction in the coating according to this development include the following:
the coating has high strength and hardness
the coating is particularly impervious. In particular, there are no channels through the coating to the surface of the main body. Diffusion of unwanted species through the coating, in particular the diffusion of carbon, is hampered.
the coating exhibits homogeneous thermal expansion
the coating has high thermal conductivity
heat transfer through the layer into the substrate occurs homogeneously.

The feature of low porosity can be achieved particularly effectively by producing the coating—indirectly or directly—by way of a vapor deposition process.

Preferably, the coating has a thickness between 0.2 μm and 200 μm; more preferably, it has a thickness between 1 μm and 20 μm.

Particularly preferably, the coating is between 3 and 10 um in thickness.

One of the advantages of a coating thickness in the specified range, especially in the preferred range, is outstanding layer adhesion even under cyclic thermal stress of the composite body.

Furthermore, a thickness in the specified range promotes faithful reproduction of a surface morphology of the substrate (in this case: the main body) and of a substrate geometry such as recesses or steps.

Moreover, a thickness in the preferred range provides a particularly balanced relationship between manufacturing complexity, layer adhesion and barrier effect, in particular with respect to inward diffusion of carbon.

It is preferable that the coating reproduces the surface morphology of the main body. In other words, it is preferable that coating is present in the same thickness along the surface of the main body. Thus, any structures on the surface of the main body are continued in the coating and are reproduced in a coating surface.

Preferably, a variation in the thickness of the coating is below 20% and more preferably below 10%.

In the case of prior known protective layers, as produced for example by pack cementation, slurry coating or powder spraying, the coating levels any structures on the surface of the main body. This can result in the existence of locally different layer thicknesses.

Since it is preferable that the variation of the thickness of the coating is low, preferably below 20% and more preferably below 10%, this means, for example, that diffusion paths through the layer are of substantially identical length everywhere on the coating.

The feature of the low variation of the thickness of the coating is advantageous for stability of the coating during use, in particular under cyclic thermal stress and/or inward diffusion of elements into the coating, in particular the inward diffusion of carbon.

A low variation in the thickness of the coating also means good reproduction of a surface morphology of the main body.

The feature of the low variation of the thickness of the coating can be determined, for example, by quantitative structural analysis. On a test specimen, the thickness of the coating can be determined transversely to the coating at multiple positions. Border areas of the main body and regions with steps, flanks, radii or the like are excluded.

The feature of a variation of the thickness of the coating of below 20% indicates that the thickness of the coating at the positions considered is within a range of ±20% with respect to the average thickness of the coating determined for the positions considered.

According to one development, at least one intermediate layer may be formed between the surface of the main body and the coating comprising tungsten carbide.

This also means that the coating is not necessarily formed directly on a surface of the main body.

An intermediate layer may be beneficial for layer adhesion of the coating and/or for increasing the barrier effect to counter inward diffusion of carbon.

According to one development, the intermediate layer consists of tungsten or a tungsten-based alloy. Accordingly, a metallic layer of tungsten or a tungsten-based alloy is formed on the surface of the main body and below the coating. A tungsten-based alloy is understood to mean a composition having at least 50 at % tungsten.

In particular, the intermediate layer of tungsten or a tungsten-based alloy comprises columnar tungsten grains.

Columnar grains have a pronounced extension. Typically, a grain extension ratio, that is a ratio of the extension along a longitudinal axis to a grain width as measured perpendicularly to the longitudinal axis, is greater than or equal to two, in particular greater than or equal to five.

A columnar microstructure has a distinctly higher thermal conductivity in a direction along the longitudinal axis of the columnar grains than transversely thereto. This can be explained by a smaller number of grain boundaries to be overcome. It is particularly advantageous when the intermediate layer of tungsten is in the form of columnar tungsten grains.

In particular, the columnar tungsten grains have a preferred orientation such that a plurality of the columnar tungsten grains are oriented substantially normal to the surface of the main body.

“Normal to the surface” means that the grains, with respect to their longitudinal axis (the axis with the greatest extent of the grain), are oriented at an angle of about 90° to the surface of the main body, which includes angular deviations of ±15° therefrom.

Preferably, at least 80% of the columnar tungsten grains have such a preferred orientation, based on a total areal proportion of columnar tungsten grains. It is particularly advantageous, especially with respect to thermal conductivity, when the intermediate layer of tungsten is in the form of columnar tungsten grains having such a preferred orientation.

One way of providing the intermediate layer of tungsten or a tungsten-based alloy is deposition by sputtering from a target of appropriate composition.

Alternatively, the intermediate layer comprises a mixture of tungsten and molybdenum.

The intermediate layer of tungsten and molybdenum creates an additional barrier against inward diffusion of carbon into the main body.

Owing to dissolution of tungsten in molybdenum, the diffusion constant of carbon is markedly reduced compared to diffusion in pure molybdenum.

Furthermore, tungsten, when present along grain boundaries of molybdenum by diffusion, can act as a carbon getter and intercept harmful inward diffusion of carbon.

More preferably, a composition of the intermediate layer is between 1 at % tungsten and 100 at % tungsten with or without the molybdenum balance and customary impurities.

According to one development, the intermediate layer contains grains made of a molybdenum-based material, at the grain boundaries of which tungsten is present. It is thus preferable that enrichment is carried out, for example by inward diffusion, at the grain boundaries of the grains made of a molybdenum-based material.

Such an intermediate layer is preferably produced by coating with tungsten and performing a subsequent heat treatment, which causes inward diffusion of tungsten into a superficial zone of the base material.

More preferably, the intermediate layer is in graduated form.

Preferably, the intermediate layer has a gradient with respect to the tungsten content such that the tungsten content in the intermediate layer decreases in the direction of the main body starting from the coating.

If the intermediate layer is in graduated form, the above tungsten contents in the intermediate layer refer to an averaged composition along the thickness of the intermediate layer.

For example, a thickness of the intermediate layer is between 500 nm and 20 μm. Preferably, the intermediate layer is between 500 nm and 8 um in thickness and more preferably between 3 μm and 5 μm in thickness.

In particular, it is proposed that the main body comprise a molybdenum alloy having carbidic constituents. In particular, carbidic constituents are in the form of dispersoids. Dispersoids refer to particles that are finely dispersed in a matrix. Dispersoids can be added as particles to the alloy or obtained by precipitation. Especially suitable as main body is the molybdenum alloy having contents of titanium, zirconium and carbon that is known as TZM. A typical composition of the alloy is Ti at 0.5 wt %, Zr at 0.08 wt % and C at 0.01-0.04 wt % (wt %=percent by weight) with the balance being formed by molybdenum.

Present in the molybdenum alloy TZM is, in particular, carbides of zirconium and titanium.

Compared to pure molybdenum, TZM is stronger and has a higher recrystallization temperature and a higher creep resistance.

The applicant has found that layer adhesion of the tungsten carbide coating on a main body made of a molybdenum alloy having carbidic constituents is further improved compared to a main body made of pure molybdenum. Without committing to a scientific explanation, it is believed that the carbidic species in the substrate (in this case: the main body) further improves the bonding of the tungsten carbide coating.

Therefore, according to a preferred development, the main body consists of a molybdenum alloy having carbidic constituents, in particular consists of TZM.

The composite body according to the invention is particularly suitable for applications of molybdenum-based materials in a carburizing atmosphere.

In the case of the composite body according to the invention, inward diffusion of carbon into the main body made of molybdenum or a molybdenum alloy is prevented effectively by the coating comprising tungsten carbide. The coating comprising tungsten carbide forms an effective diffusion barrier to counter inward diffusion of carbon into the molybdenum base material.

The diffusion constant of carbon in tungsten carbide is lower than the diffusion constant of carbon in molybdenum by two or more powers of ten.

If molybdenum is used in a carburizing atmosphere without protection, molybdenum carbide, in particular Mo₂C, will form on the surface. The compound Mo₂C has a greater coefficient of thermal expansion (CTE) than metallic molybdenum.

A difference in the coefficients of thermal expansion, especially in connection with a layer and a substrate, is referred to as a “CTE mismatch”.

In addition to other influencing factors, carburization of the molybdenum base material and the described CTE mismatch can cause flaking and loss of substance in respect of base material.

Applications in which the CTE mismatch is particularly disadvantageous are processes with cyclic thermal stress, such as in the case of use of molybdenum structural components in furnace plants with graphite heaters or the use of molybdenum substrates in carbon-containing plasma, such as in diamond synthesis (production of artificial diamonds).

Likewise relevant are applications in reactor construction, such as heat exchangers or vessels in reactor construction.

In the case of the composite body according to the invention, this disadvantageous effect is prevented or at least distinctly reduced.

Another advantage of the coating is that a vapor pressure on a surface coated in such a manner is distinctly reduced compared to an uncoated main body.

Therefore, the composite body potentially leads to fewer unwanted species being introduced into a process space compared to an uncoated main body. This is particularly noticeable in the case of applications of the composite body according to the invention in low-pressure or vacuum applications.

Protection is also sought for a use of an above-described composite body as a component in a high-temperature furnace. This includes, in particular, radiation shields as well as holders and charging devices. Protection is also sought for a use of an above-described composite body as a substrate in the production of synthetic diamonds. Also relevant are applications of the composite body as components in chemical reactors.

Protection is sought for a method for producing a composite body.

In the method, a coating comprising tungsten carbide is formed at least sectionally on a main body made of a molybdenum-based material, for example molybdenum or a molybdenum alloy.

The method comprises the steps of:
providing a main body made of a molybdenum-based material,
a) coating a surface of the main body with metallic tungsten in order to form a metallic tungsten film on the surface and subsequently performing at least partial carburization of the metallic film to form tungsten carbide or
b) coating a surface of the main body by deposition of tungsten carbide by sputtering from a tungsten carbide target or by reactive sputtering from a tungsten-containing target in a carburizing atmosphere.

In both method variants, a layer is applied by a vapor deposition process, which results in the above-explained advantages of the coating. The coating of tungsten carbide can be formed indirectly, according to the first alternative, or directly, according to the second alternative of the method.

It would also be conceivable to combine the two method variants.

In one development of the method, an intermediate layer may be formed on a surface of the main body on which the coating of tungsten carbide is subsequently formed.

The intermediate layer may be a layer of tungsten.

An intermediate layer of tungsten is obtainable, for example, by carrying out the method variant of indirect production of the coating of tungsten carbide and not completely carburizing through the previously deposited metallic tungsten film.

The parameters in relation to this can be determined by way of tests by a person skilled in the art.

The intermediate layer is in particular formed from molybdenum with tungsten.

An intermediate layer of tungsten and molybdenum creates an additional barrier against inward diffusion of carbon into the main body.

Regarding the production of the intermediate layer of molybdenum with tungsten, preference is given to depositing metallic tungsten on the main body, for example by sputtering from a tungsten target. Thereafter, the main body coated in such a manner is subjected to heat treatment such that tungsten diffuses into the molybdenum-based main body.

The method for producing the composite body is more particularly elucidated in what follows.

### Production Example 1

Molybdenum and TZM circular blanks with dimensions of Ø 10 mm×5 mm were first coated with a metallic tungsten film of about 5 μm in thickness by sputtering from a tungsten target.

The samples were then heat-treated in a tube furnace (manufacturer: Reetz GmbH) under a carburizing atmosphere. The carburizing gas mixture used was Ar/CH₄ (argon/methane) comprising argon at 99 vol %+methane at 1 vol % at a flow rate of 10 L/h. Heating was carried out to 1000 °C at a ramp of 15 K/min and to the relevant test temperature at 10 K/min. Cooling was carried out under the same gas mixture.

At a holding time of 15 hours at 1300 °C, complete carburization of the tungsten into tungsten carbide was observed.

Phase analysis using XRD (X-ray diffraction) revealed the presence of hexagonal WC. At lower holding times, W₂C was also detected in addition to WC.

### Production Example 2

According to an alternative route of production, test specimens made of TZM were coated by sputtering from a WC target. The samples were sandblasted before coating. In order to compensate for the different sputtering rates of tungsten and carbon, the target was doped with graphite in a WC/C (tungsten carbide to carbon) ratio of 85/15 mol % (mole percent). This achieved tungsten carbide of the stoichiometry WC in the coating.

With a coating time of 20 minutes, a coating of cubic WC having a layer thickness of 4.5 μm was produced. The coating had a nanocrystalline structure. Layer adhesion was excellent, and there were no detectable pores.

Producing the coating of tungsten carbide, or at least comprising tungsten carbide, by a vapor deposition process, either indirectly or directly, is associated with important structural properties and advantages.

Since the coating is produced—indirectly or directly—by a vapor deposition process, the coating has particularly low porosity.

Furthermore, layer adhesion is outstanding.

Since the grains of the coating grow on the surface of the main body in a vapor deposition process, there is a chemical bond and thus more intimate cohesion between the main body and the coating than in the case of purely mechanical interlocking, such as in the case of powder application.

In particular, there may also be, at least in some cases, an epitaxial connection between the grains of the main body and the grains of the coating.

A further feature that can be adjusted by depositing the coating by vapor deposition is the formation of a microstructure having at least a proportion of columnar grains.

In summary, the features and associated advantages of the coating produced by vapor deposition include the following:
low porosity: high strength, high imperviousness, good barrier effect to counter diffusion
fine granularity: high strength and toughness
contour accuracy: no levelling of a surface structure of the substrate
layer adhesion: intimate chemical/metallurgical bonding in contrast to sintered or sprayed layers
microstructure: homogeneous structure, low variation of grain sizes, with or without preferred orientation of the grains.

A person skilled in the art can readily distinguish a coating produced by vapor deposition from sintered or sprayed layers.

Further advantages and benefits of the invention will become apparent from the following description of exemplary embodiments with reference to the accompanying drawings.

In the Drawings:

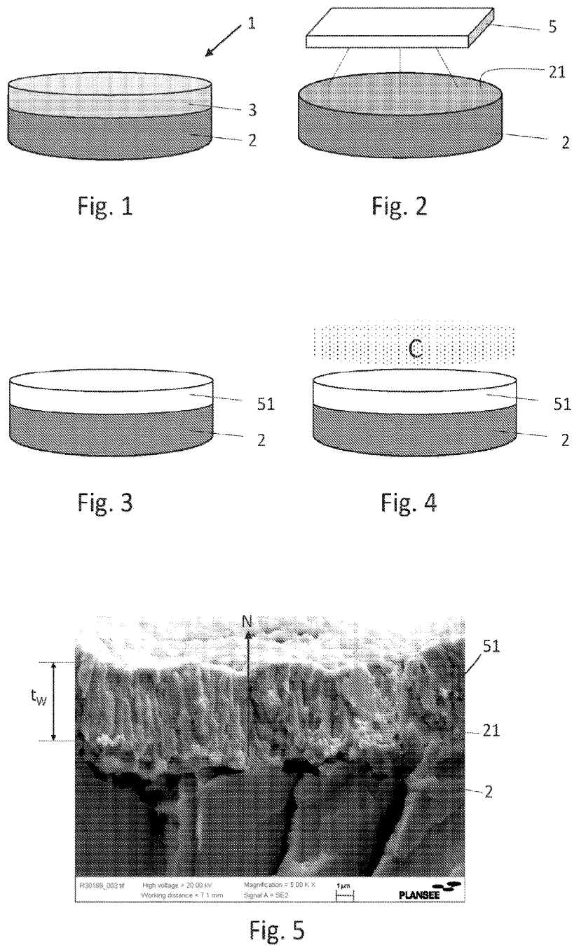

FIG. 1: shows a composite body in a first exemplary embodiment

FIG. 2: shows a step in producing a composite body

FIG. 3 shows a next step in producing a composite body

FIG. 4 shows a further step in producing a composite body

FIG. 5 shows a scanning electron micrograph of an intermediate stage in producing a composite body

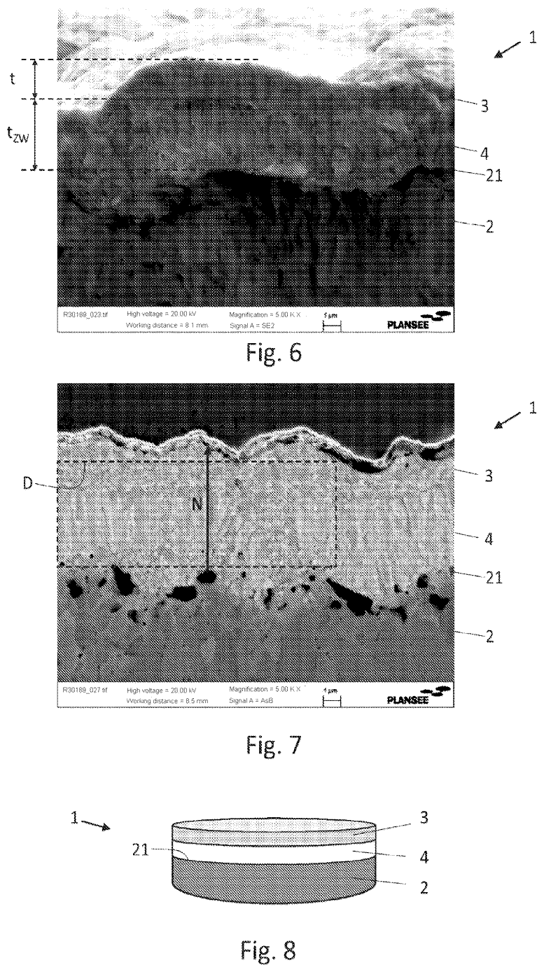

FIG. 6 shows a scanning electron micrograph of a composite body

FIG. 7 shows a scanning electron micrograph (fracture pattern) of a composite body having an intermediate layer

FIG. 8 schematically shows the structure of a composite body having an intermediate layer

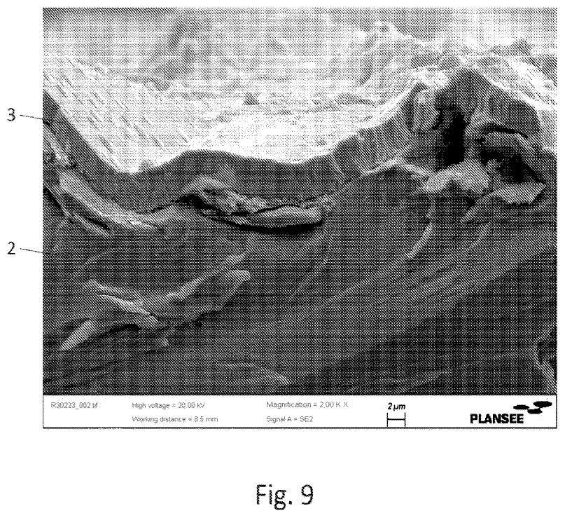

FIG. 9 shows a scanning electron micrograph (fracture pattern) of a composite body in a further exemplary embodiment

FIG. 1 schematically shows a composite body 1 in a first exemplary embodiment. The composite body 1 comprises a main body 2 made of a molybdenum-based material, on the surface of which a coating 3 based on tungsten carbide is formed at least sectionally. For the sake of clarity, the proportions are not reproduced to scale. In reality, the coating 3 is generally much thinner in relation to a thickness of the main body 2.

FIG. 2 schematically shows a first step in producing a composite body 1 according to a first method variant. Here, metallic tungsten is deposited on a surface 21 of the main body 2 by sputtering of a target 5. As an alternative to cathode sputtering, it would also be possible to deposit tungsten by CVD (chemical vapor deposition). In the case of the CVD variant, a gaseous and general organic precursor is passed over a substrate. For example, tungsten is deposited by using tungsten hexafluoride (WF₆) as the precursor.

Following deposition of the precursor, the aids used for transferring the metal element (in this case: tungsten) are desorbed, thereby leaving a metallic tungsten film on the surface 21 of the main body 2.

The method step illustrated in FIG. 2 yields the main body 2 having a metallic tungsten film 51 that can be seen in FIG. 3.

FIG. 4 illustrates a subsequent method step in which the metallic tungsten film 51 is carburized with carbon (“C”). A production example for converting the metallic tungsten film 51 into tungsten carbide is specified in the description.

By carburizing the metallic tungsten to form tungsten carbide, a composite body 1 according to FIG. 1 is obtained.

The metallic tungsten film 51 thus serves as the precursor layer of the coating 3.

Alternatively, the composite body 1 can be obtained by directly forming a coating 3 based on tungsten carbide on a main body 2. This can be done, for example, by cathode sputtering from a target based on tungsten carbide.

Optionally, processing steps to smooth and/or clean the composite body 1 may be carried out.

For example, it may be useful to perform gentle blasting or grinding of the coating 3. Preference is given to using tungsten carbide as the blasting material in order to avoid contamination of the coating 3.

FIG. 5 shows a scanning electron micrograph of a main body 2 made of a molybdenum-based material, TZM in the present exemplary embodiment, having a metallic tungsten film 51, in accordance with the situation in FIG. 3. The tungsten film 51 was deposited by cathode sputtering.

As sample preparation, the tungsten-coated sample was fractured. A fracture pattern is therefore shown here.

In this example, a layer thickness t_{W} of the metallic tungsten film 51 was about 5 μm.

The columnar tungsten grains having a preferred orientation relative to the surface 21 of the main body 2 can be clearly seen. The columnar tungsten grains are oriented substantially perpendicular to the surface 21. In other words, longitudinal axes of the columnar tungsten grains extend substantially parallel to a surface normal N of the surface 21 of the main body 2.

In the present example, an extension of the columnar tungsten grains parallel to the surface normal N is such that at least one to two grains are formed along the layer thickness t_{W}.

In the present example, a grain width of the columnar tungsten grains normal to their longitudinal axis was about 200 nm.

In the present example, the columnar tungsten grains typically have grain lengths corresponding to half the layer thickness of the metallic tungsten film 51. A grain extension ratio of the columnar tungsten grains is therefore about 12.5 from the ratio of half the layer thickness (2.5 μm) to a grain width (0.20 μm).

It can also be seen that the metallic tungsten film 51 reproduces a morphology of the main body 2. Structures on the surface 21 of the main body 2 are continued in the metallic tungsten film 51.

The layer thickness t_{W}of the metallic tungsten film 51 is substantially constant along the surface 21 of the main body 2.

The metallic tungsten film 51 has outstanding layer adhesion to the main body 2.

FIG. 6 shows a scanning electron micrograph of a composite body 1 having a main body 2, made of TZM in this case, having a coating 3 of tungsten carbide.

A fracture pattern is shown here.

The coating 3 in this exemplary embodiment was obtained by carburizing a metallic tungsten precursor layer.

The composite body 1 in this exemplary embodiment has an intermediate layer 4 of metallic tungsten that is present between the surface 21 of the main body 2 and the coating 3 of tungsten carbide. In the example, a thickness t of the coating 3 was about 2 μm, and a thickness t_{ZW}of the intermediate layer 4 was about 3 μm.

By varying the carburization conditions, the ratio between the thicknesses of the intermediate layer 4 and the coating 3 of tungsten carbide can be adjusted as desired.

A total thickness (t+t_{ZW}) of the coating 3 and the intermediate layer 4 exhibits low variation. The target is a variation of below 20%.

In the present example, the variation of the total thickness (t+t_{ZW}) of the coating 3 and the intermediate layer 4 was below 10%, which is also particularly preferred.

In relation to this, the total thickness (t+t_{ZW}) was measured at ten different sites under a scanning electron microscope, the sites being at least one total thickness apart and the section viewed being within 5000 μm. An average total thickness was determined from the ten measurements.

A deviation of the individual thicknesses from the average layer thickness was below 10%.

Granular tungsten grains can be seen in the intermediate layer 4.

The zone carburized to form tungsten carbide and corresponding to coating 3 has fine-crystalline tungsten carbide grains.

FIG. 7 shows a scanning electron micrograph of the same exemplary embodiment as shown in FIG. 6, and in the present case, an image of an etched cut was recorded.

The columnar tungsten grains in the intermediate layer 4 can be clearly seen.

The columnar tungsten grains are oriented substantially perpendicular to the surface 21. In other words, longitudinal axes of the columnar tungsten grains extend substantially parallel to a surface normal N of the surface 21 of the main body 2. The expression “substantially perpendicular” also encompasses angular deviations having absolute values of ≤15°.

According to a preferred development, columnar tungsten grains have a preferred orientation substantially normal to the surface 21 of the main body 2, which includes angular deviations of ≤15° therefrom.

The microstructure of the carburized region, i.e., the coating 3, comprises fine-crystalline tungsten carbide grains.

A dashed box highlights an image section “D” on which pore fraction was measured by quantitative structural analysis.

A person skilled in the art can identify pores in the microstructure and mark them in a suitable image processing program. The image processing program can add up the marked pore areas.

The section shown in FIG. 7 could optionally be used for comparison.

The total area of the selected image section was about 82 μm² . A total area of pores in the selected image section was 0.75 μm².

The pore fraction is determined from the ratio of the total area of pores to the total area of the selected image section and was 0.92% in the present example. This means that the pore fraction in the coating 3 and the intermediate layer 4 was below 1%.

Preferably, the pore fraction in the coating 3 is below 10%. More preferably, the pore fraction in the coating 3 is below 5%, more preferably below 3% and yet more preferably below 1.5%.

The dark regions on the surface 21 are not pores, but residues of blasting material.

FIG. 8 schematically shows the structure of a composite body 1 having a coating 3 of tungsten carbide. The composite body 1 has an intermediate layer 4 of metallic tungsten that is present between the surface 21 of the main body 2 and the coating 3 of tungsten carbide.

FIG. 9 shows a scanning electron micrograph of a composite body 1 having a main body 2, made of TZM in this case, having a coating 3 of tungsten carbide. The image shows a fracture pattern.

In the present exemplary embodiment, the coating 3 of tungsten carbide has been applied directly by sputtering using a tungsten carbide target. In the exemplary embodiment, the thickness t of the coating is about 4 μm and has a particularly low variation in thickness. It can be clearly seen that the coating 3 reproduces surface contours of the substrate (in this case: the main body).

The microstructure of the coating 3 is extremely fine and consists of nanocrystalline tungsten carbide grains. In the exemplary embodiment, a grain size is a few nanometers and cannot be resolved by the scanning electron microscope used under the contrast mode selected. In the present exemplary embodiment, the coating is nanocrystalline throughout.

The coating 3 formed in such a manner has outstanding layer adhesion on the substrate, the main body 2.

Owing to the fine granularity, the coating is high-strength and at the same time tough.

Furthermore, the coating is virtually pore-free. No pores were detected. As already described at the start, the particular advantages of such a pore-free layer include strength and imperviousness.

As a departure from the present exemplary embodiment, an intermediate layer may additionally also be formed for the variant of the coating deposited from a WC target.

1-12. (canceled)

13. A composite body, comprising:
a main body made of a molybdenum-based material; and
a coating including tungsten carbide formed at least sectionally on said main body;
said coating having a microstructure substantially formed of at least one of fine-crystalline or nanocrystalline tungsten carbide grains.

14. The composite body according to claim 13, wherein a pore fraction in said coating is below 10%.

15. The composite body according to claim 13, wherein a variation of a thickness of said coating is below 20%.

16. The composite body according to claim 13, which further comprises at least one intermediate layer formed between a surface of said main body and said coating.

17. The composite body according to claim 16, wherein said at least one intermediate layer is formed of tungsten or a tungsten-based alloy.

18. The composite body according to claim 16, wherein said at least one intermediate layer includes molybdenum and tungsten.

19. The composite body according to claim 16, wherein said at least one intermediate layer contains grains made of a molybdenum-based material, and tungsten being present at grain boundaries of said grains.

20. The composite body according to claim 13, wherein said main body includes a molybdenum alloy having carbidic constituents.

21. The composite body according to claim 13, wherein the composite body is a component of a high-temperature furnace.

22. The composite body according to claim 13, wherein the composite body is a substrate configured to be used in a production of synthetic diamonds.

23. A method of using a composite body, the method comprising:
using the composite body according to claim 13 as a substrate in a production of synthetic diamonds.

24. A method for producing a composite body, the method comprising steps of:
providing a main body made of a molybdenum-based material; and
forming a coating including tungsten carbide on a surface of the main body by:
performing vapor deposition to deposit a film including metallic tungsten on the surface of the main body and subsequently performing at least partial carburization of the metallic film to form tungsten carbide,
or
performing vapor deposition to deposit the coating including tungsten carbide by sputtering from a tungsten carbide target or by reactive sputtering from a tungsten-containing target in a carburizing atmosphere.
